(19) United States
(12) Patent Application Publication
(10) Pub. No.: US 2007/0200164 A1
(43) Pub. Date: Aug. 30, 2007

(54) Single poly embedded memory structure and methods for operating the same

(75) Inventor: Chao-I Wu, Tainan (TW)

Correspondence Address: BAKER & MCKENZIE LLP;PATENT DEPARTMENT, 2001 ROSS AVENUE, SUITE 2300, DALLAS, TX, 75201, US

(73) Assignee: Macronix International Co., Ltd.

(21) Appl. No.: 11/363,313

(22) Filed: Feb. 27, 2006

(51) Int. Cl. H01L 29/788

(52) U.S. Cl. 257/315; 438/201; 257/E29.305

(57) ABSTRACT

A single poly embedded memory structure comprises an access transistor and a storage device formed on a silicon substrate. The access transistor comprises source and drain diffusion regions implanted in the silicon substrate and a polysilicon control gate formed over the silicon substrate between the source and drain diffusion regions. The storage structure comprises a source and drain diffusion regions implanted in the silicon substrate and a polysilicon floating gate formed over the silicon substrate between the source and drain diffusion region; however, the source diffusion region comprises a double diffusion structure.

### BACKGROUND

1. Field of the Invention

The embodiments described below related to non-volatile memory devices, and more particularly to low cost single poly embedded memory structures that are compatible with conventional CMOS processes.

2. Background of the Invention

It is often desirable to have available a low cost, low-density non-volatile memory device. One way to provide low cost memory devices is to design them so that they are compatible with standard CMOS processes. Unfortunately, process complexities hinder the incorporation of traditional non-volatile memory devices in the CMOS circuits. For example, the need for multiple polysilicon layers, different gate oxide thicknesses, and modified diffusion doping profiles can lead to added process complexities and costs that prevent the realization of low cost, low-density non-volatile memory devices.

Single poly embedded memory structures that have been introduced as low cost, low-density non-volatile memory device options. FIG. 1 is a diagram illustrating a conventional single poly embedded memory structure 100. As can be seen, single poly embedded memory structure 100 comprises a substrate 102 and three diffusion regions 104, 106, 108 implanted within substrate 102. In this case, substrate 102 is a p-type silicon substrate, while diffusion regions 104, 106, and 108 are N+ type diffusion regions. A dielectric layer 112, in this case an oxide layer, is then formed on top of substrate 102. Polysilicon gate structures 109 and 110 are then formed on top of oxide layer 112. In this case, gate structures 109 and 110 are n-type polysilicon gate structures. Gate structure 109 can be connected with a control line 116 and can act as a control gate, while gate 110 is left floating and acts as a floating gate. A select line 114 can be connected with diffusion region 108, while a bit line 116 can be connected with diffusion region 104.

Accordingly, structure 100 can be viewed as a pair of transistors in series with each other. The transistor structure on the right hand side, with floating gate 110, can act as a storage device, while the transistor structure on the left hand side can act as an access transistor for the storage device on the right hand side. By applying the correct voltages to select line 114, control gate 116, bit line 118, and substrate 102, floating gate 110 of the storage device can be programmed, erased, and the state of the storage device can be read.

Structure 100 of FIG. 1 is limited, however, in that structure 100 can only be operated by channel hot hole programming and channel hot electron erase.

Structure 200 in FIG. 2 also provides a non-volatile memory cell that uses standard CMOS transistors. Thus, no additional masking or processing steps are necessary, which provides for lower costs and process compatibility.

To selectively program and read cell 200, and NMOS access transistor 204 is placed in series with storage device 202. Two transistors are thus required for each cell 200. In a cell 200, programming is achieved by injecting electrons into the floating gate of storage device 202. Thus, an un-programmed device 200 conducts little more than a small leakage current, while a programmed cell 200 can conduct a large amount of current. This is because the increased number of electrons in the floating gate of storage device 202 induces inversion of the p channel between the source and drain diffusion regions.

Because the gate of PMOS storage device 204 is floating, it can be used as a charge storage device. Charge injection into the floating gate of storage device 202 is achieved by applying a minimum source drain potential of a certain voltage. This bias causes a programming drain current to flow through the device due to a combination of capacitive coupling between the source and the floating gate. The whole current generates electrons in the drain's high field region by impact ionization. Electrons are injected in the gate oxide and accumulated in the floating gate. This negative gate charge induces a conductive inversion layer at the Si/SiO2 interface, and the device essentially becomes a depletion mode transistor.

The cell can be programmed by simultaneously applying a pulse of positive polarity of the bit line and the word line. With the NMOS device turned on, current can flow through the memory device. At a sufficiently large voltage, the PMOS storage structure is programmed. To read cell 200, a reading voltage is applied to the bit line while a read voltage is applied to the word line.

Bulk erasure device 200 is accomplished through ultraviolet (UV) exposure. Unfortunately, since the implementation of memory device 200 has no control gate, it cannot be erased electrically.

### SUMMARY

A single poly embedded memory structure comprises an access transistor and a storage device formed on a silicon substrate. The access transistor comprises source and drain diffusion regions implanted in the silicon substrate and a polysilicon control gate formed over the silicon substrate between the source and drain diffusion regions.

The storage structure comprises a source and drain diffusion regions implanted in the silicon substrate and a polysilicon floating gate formed over the silicon substrate between the source and drain diffusion region; however, the source diffusion region comprises a double diffusion structure. For example, in embodiments where the silicon substrate is a p-type silicon substrate, the double diffusion structure can comprise an N+ type diffusion region implanted in the p-type silicon substrate and a P+ type diffusion region implanted in the N+ type diffusion region, thus forming the double diffusion structure.

In one aspect, the single poly embedded memory structure can be programmed using channel hot electron techniques.

In another aspect, the single poly embedded memory structure can be programmed using band-to-band hot electron techniques.

In still another aspect, the single poly embedded memory structure can be programmed using source induced band-to-band hot electron techniques.

In still another aspect, the single poly embedded memory structure can be erased using band-to-band hot hole techniques.

In still another aspect, the single poly embedded memory structure can be erased using Fowler-Nordheim erase techniques.

In still another aspect, the single poly embedded memory structure can be bulk erased using ultra violet radiation.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 is a diagram illustrating a conventional single poly embedded memory structure;

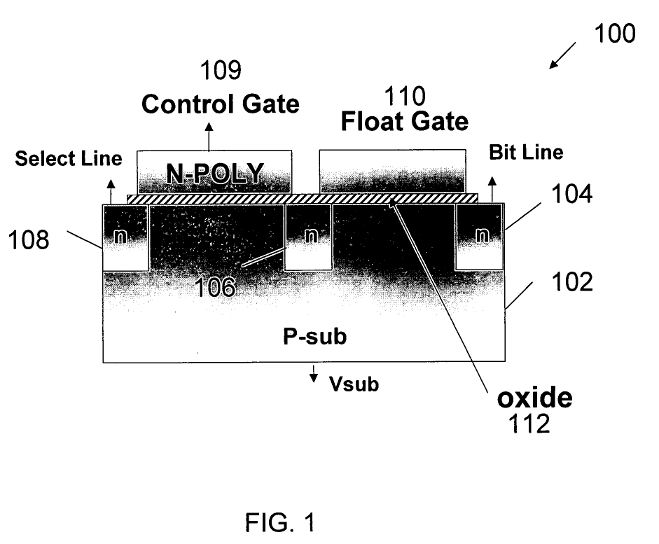

FIG. 2 is a diagram illustrating another conventional single poly embedded memory structure;

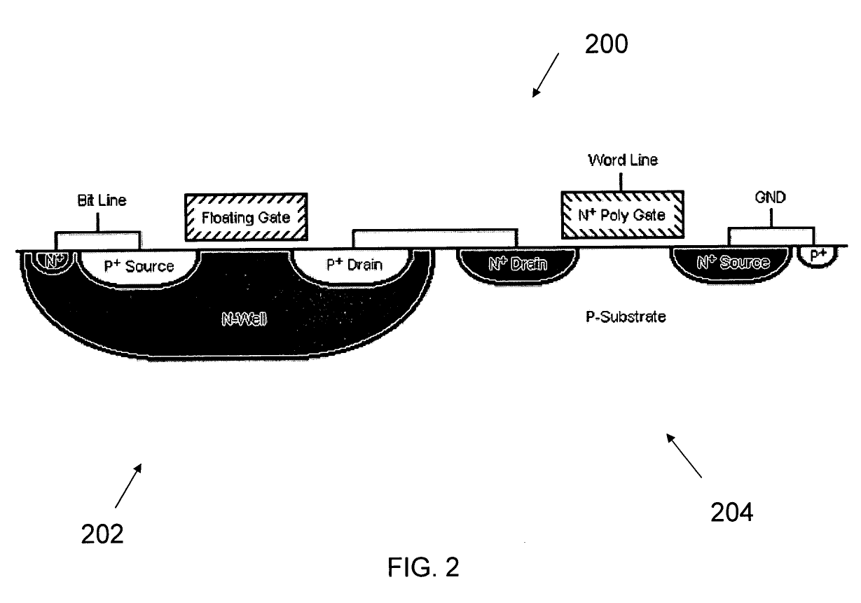

FIG. 3 is a diagram illustrating an example single poly embedded memory structure comprising a double diffusion structure in accordance with one embodiment;

FIG. 4 is a diagram illustrating channel hot electron programming of the structure of FIG. 3;

FIG. 5 is a diagram illustrating band-to-band hot electron programming of the structure of FIG. 3;

FIG. 6 is a diagram illustrating source induced band-to-band hot electron injection programming of the structure of FIG. 3;

FIG. 7 is a diagram illustrating band-to-band hot hole injection erasure of the structure of FIG. 3;

FIG. 8 is a diagram illustrating a Fowler-Nordheim erase operation for the structure of FIG. 3;

FIGS. 9a and 9b are diagrams illustrating bulk UV erase of the structure of FIG. 3; and

FIGS. 10A and 10B are diagrams illustrating an example read operation for the structure of FIG. 3.

### DETAILED DESCRIPTION

The embodiments described below are directed to a single poly embedded memory structure that is compatible with conventional CMOS processes. Accordingly, low cost, low-density non-volatile memory devices can be achieved using the embodiments described below. The single poly embedded memory structures described below include a double diffusion structure. As a result, a plurality of techniques can be used to both programs and erase the structures described below. For example, in addition to both UV erase operations, the device can be erased electrically using one or more techniques.

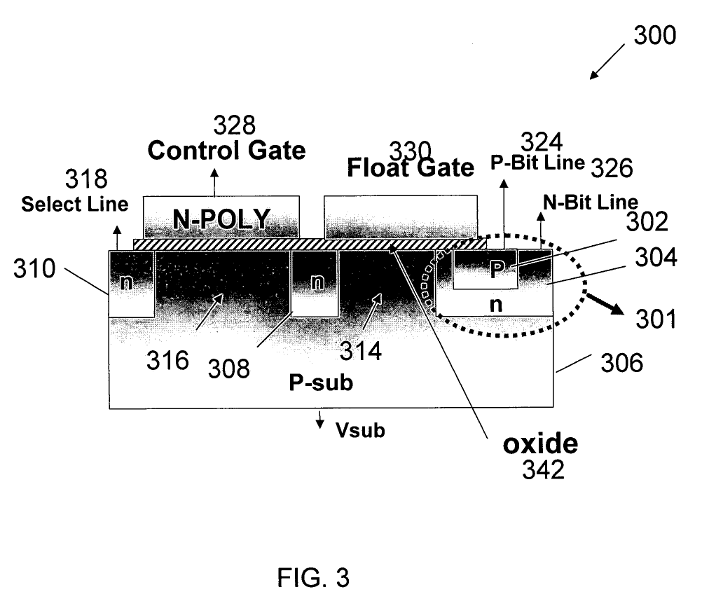

FIG. 3 is a diagram illustrating a single poly embedded memory structure 300 comprising a double diffusion structure 301 in accordance with one embodiment of the systems and methods described herein. Structure 300 comprises a silicon substrate 306 with 3 diffusion regions 301, 308, and 310 implanted therein. In the embodiment of FIG. 3, silicon substrate 306 is a P-type silicon substrate, and each of diffusion regions 301, 308, and 310 comprises an N+ type diffusion region implanted in silicon substrate 306. In addition, however, double diffusion structure 301 further comprises a P+ type diffusion region 302 implanted in N+-type diffusion region 304. Diffusion regions 302 and 304 comprise double diffusion structure 301.

A dielectric layer 342, in this case an oxide layer, is then formed over substrate 306 as illustrated. N-type polysilicon gates 328 and 330 are then formed on oxide layer 342.

Thus, structure 300 comprises 2 transistor structures. The N-type polysilicon gate can be used to store charge in the floating gate for memory applications. N-type polysilicon gate 328 can be connected with a control gate input, and therefore the transistor structure on the left can act as an access device for accessing the data stored in the storage structure on the right. Diffusion region 310 can be connected with select line 318, while diffusion region 302 can be connected with a P bitline 324, and diffusion region 304 can be connected with an N bitline 326.

As described in more detail below, by applying the appropriate programming voltages to select line 318, control gate 328, P bitline 324, N bitline 326, and substrate 306, charged can be stored in floating gate 330 via a variety of mechanisms. Applying the correct voltages to select line 318, control gate 328, P bitline 324, N bitline 326 and substrate 306, the charged status of floating 330 can be read. Structure 300 can also be erased either electrically or through a UV bulk erase process as described below.

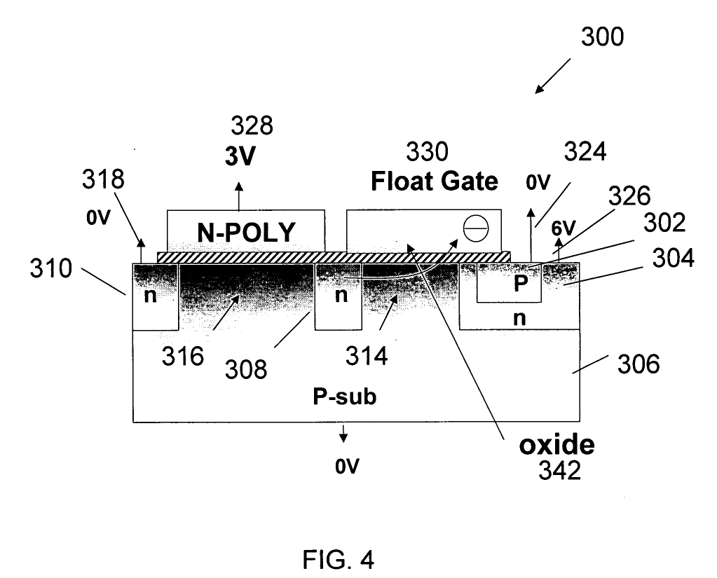

FIG. 4 is a diagram illustrating one example method for programming structure 300. In FIG. 4, a channel hot electron technique is used to store charged in floating gate 330. Specifically, creating a potential between diffusion region 301 and diffusion region 308 which will cause a drain current to flow through the device. The drain current will generate electrons in the high field via impact ionization. Electrons 332 can then be injected into the gate oxide and accumulated in floating gate 330. As a result, a storage device on the right hand side of structure 300 essentially experiences a high-Vt state that turns off the current path of the storage device.

Structure 300 can be programmed in the method described in relation to FIG. 4 by simultaneously applying a positive voltage to N bitline 326 and control gate 328. In the example of FIG. 4, a 3 volt programming voltage is applied to control gate 328, while a 6 volt programming voltage is applied to N bitline 326. Select line 318, P bitline 324 and substrate 306 can all be tied to zero volts during the programming operation.

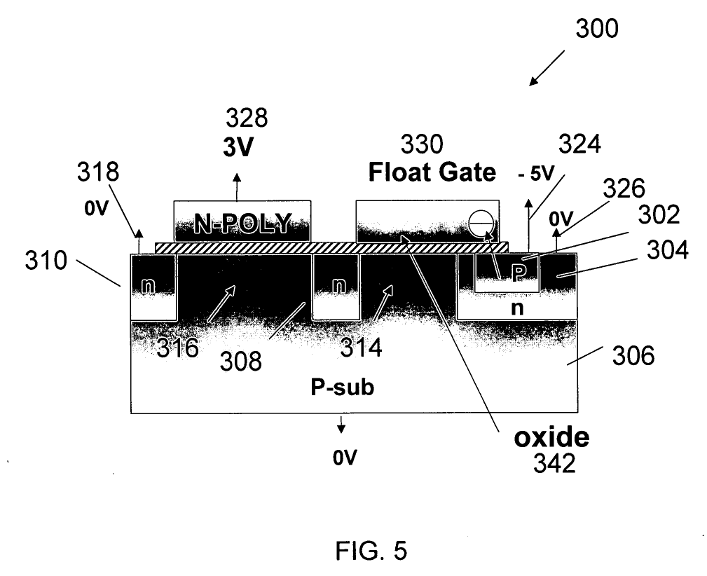

FIG. 5 is a diagram illustrating a method of programming structure 300 that uses band-to-band hot electron injection. Thus, in the process illustrated in FIG. 5 a voltage differential is created between P+ type diffusion region 302 and floating gate 330. The hot electrons will get their energy from the voltage differential and will start to be accelerated; however, the hot electrons will not travel into channel 314 due to the surrounding diffusion region 304. Once the hot electrons have sufficient energy, they will be attracted to floating gate 330, where they will accumulate as stored charge. Once there is a sufficient amount of electrons 332 stored in floating gate 330, the process will come to an end because the electric field for oxide layer 342 will start to repulse the electrons.

In the example of FIG. 5, a negative programming voltage, e.g., −5 volts is applied to P bitline 324, while a positive programming voltage, e.g., 3 volts, is applied to control gate 328. Select line 318, N bitline 326, and substrate 306 can all be tied to zero volts during the programming operation illustrated in FIG. 5.

Again, the storage structure on the right hand side of structure 300 will act as a accumulation mode transistor once sufficient charge is stored in floating gate 330.

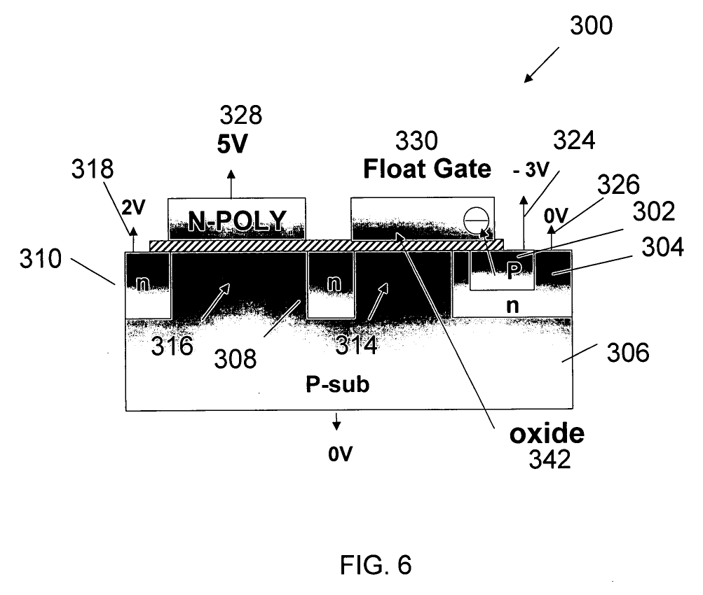

FIG. 6 is a diagram illustrating an example method for programming structure 300 using source induced band-to-band hot electron injection. In the example of FIG. 6, a programming voltage of approximately 5 volts is applied to control gate 328 while a −3-volt programming voltage is applied to P bitline 324. This voltage differential will cause electrons 332 to be injected from diffusion region 302 through oxide layer 342 into floating gate 330. Additionally, a programming voltage is applied to select line 318 which creates a voltage differential between diffusion region 301 and diffusion region 310. This voltage differential can provide energy to electrons 332 in order to assist in their ability to transition from diffusion region 302 to floating gate 330.

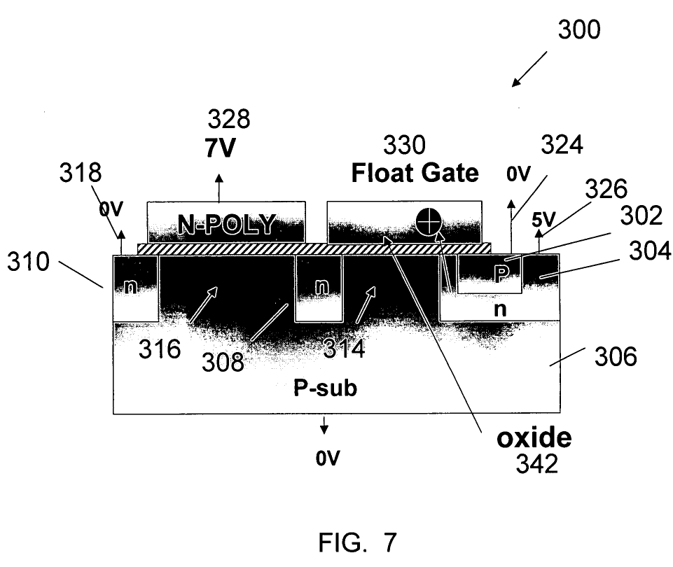

As mentioned above, a variety of erase techniques can be used to erase the storage device on the right hand side of structure 300. For example, FIG. 7 is a diagram illustrating a method for erasing structure 300 that uses band-to-band hole injection in accordance with one embodiment. Thus, a voltage differential between gate 328 and diffusion region 304 is created by applying a positive erase voltage to control gate 328 and to diffusion region 304. Select line 318, P bitline 324 and substrate 306 can all be tied to zero volts during the erase operation. The voltage differential will cause holes to be attracted to floating gate 330. Thus, holes will be injected from diffusion region 304 and the floating gate 330 where they will compensate for the electrons previously injected in the floating gate 330. In the example of FIG. 7, an erase voltage of 7 volts is applied to control gate 328, while 5 volts is applied to N bitline 326.

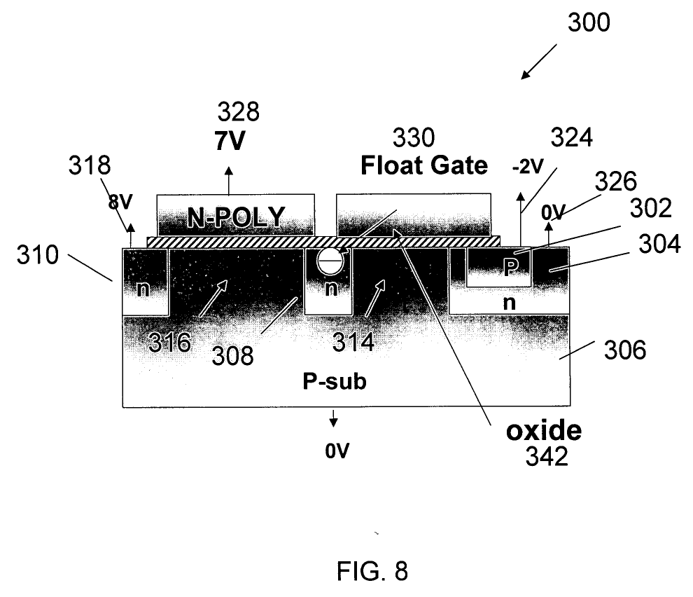

FIG. 8 is a diagram illustrating a method for erasing structure 300 that uses Fowler-Nordheim (FN) erase techniques. In the example of FIG. 8, drain side tunneling is used. In order to induce electron tunneling a positive control voltage is applied to control gate 328 and to select line 318. Additionally, a negative voltage is applied to P bitline 324, while N bitline 326 and substrate 306 are tied to zero volts. Specifically, in the example of FIG. 8, 8-volt is applied to select line 318, 7-volt is applied to control gate 328, and −2 volts is applied to P bitline 324. These combination of voltages will cause electrons 332 to tunnel from floating gate 330 through oxide layer 342 and into diffusion region 308 as illustrated.

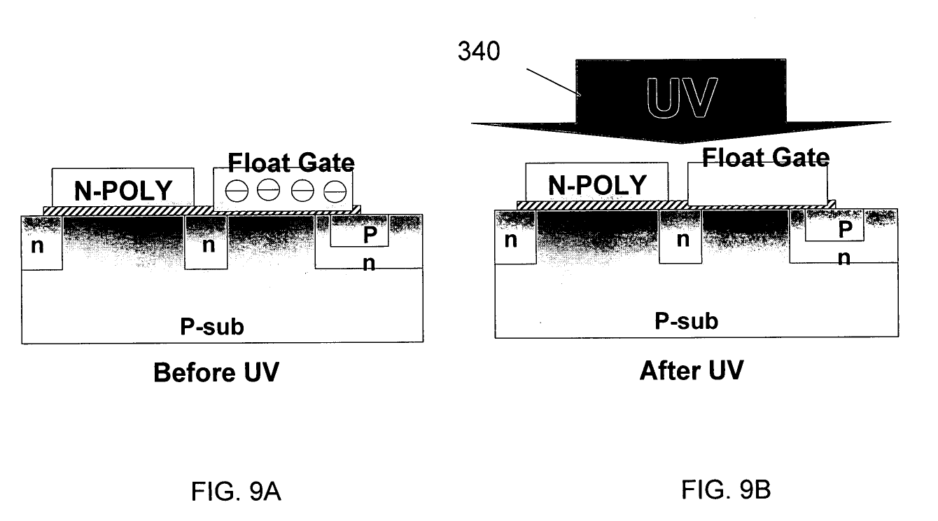

FIGS. 9A and 9B are diagrams illustrating a bulk UV rays of structure 300. FIG. 9A illustrates structure 300 after it has been programmed using one of the techniques described above. In order to erase structure 300, device 300 can be exposed to UV radiation 340 as illustrated in FIG. 9B. As will be understood, UV rays 340 will reduce the threshold voltage for the storage structure and allow the electrons to surmount the energy barrier of the floating gate and diffusing the substrate 306.

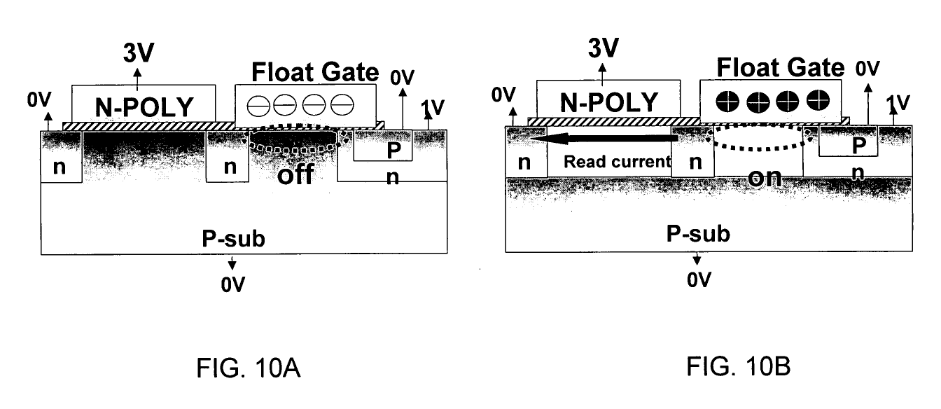

FIGS. 10A and 10B are diagrams illustrating methods for reading the programming state of the storage structure of structure 300. Thus, in FIG. 10A, floating gate 330 has been programmed by storing charge 332 and a floating gate using one of the methods described above. In order to read structure 300, a positive read voltage is applied to control gate 328 while a positive voltage is also applied to N bitline 326. Because charge 332 is stored in floating gate 330 in FIG. 10A, application of the read voltages illustrated will not be sufficient to allow a current to flow through channel 314. This is because the increased number of electrons in the floating gate of the storage device induces accumulation of p channel 314 between the source and drain diffusion regions. Thus, the storage transistor structure on the right is essentially turned off as illustrated. And no current will flow through to select line 324.

Conversely, in FIG. 10B charge 332 is not stored in a floating gate 330. An un-programmed device 300 conducts a large amount of current. Thus, when read voltages are applied, the storage transistor structure is essentially on which means that current cannot flow though channel 314 which will create a read current in channel 316 of the access structure. Read current 344 can then be detected at select line 318.

In the examples of FIGS. 10A and 10B, 3 voltage can be applied to control gate 328 while a 1-volt read voltage is applied to N bitline 326. Select line 318, P bitline 324, and substrate 306 can then be tied to zero volts.

Accordingly, a single poly embedded memory structure, such as structure 300 is compatible with conventional CMOS processing techniques, which allows for a low cost, low-density memory structure. Further, structure 300 has the advantage that it can be programmed using a variety of electrical programming techniques and can be erased using either electrical erase techniques or bulk UV rays operations.

In the examples illustrated above, the access transistor and storage transistor structures are both NMOS structures and that they comprise N-type diffusion regions and planted in the P-type silicon substrate. A PMOS structures in the N-type silicon substrate can also be used.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

What is claimed is:

1. A single poly memory device, comprising:
a substrate;
a control gate input;
a pair of bit line inputs;
a select input;
an access device formed on the substrate, comprising a control gate connected with the control gate input, a shared diffusion region formed in the substrate, and a diffusion region formed in the substrate and connected with a select input; and
a storage device formed on the substrate, the storage device comprising a floating gate, the shared diffusion region, and a double diffusion structure.

2. The single poly memory device of claim 1, wherein the double diffusion structure comprises a first diffusion region formed in a second diffusion region.

3. The single poly memory device of claim 2, wherein the substrate is a P type silicon substrate, and wherein the first diffusion region is a P type diffusion region and the second diffusion region is a N type diffusion region.

4. The single poly memory device of claim 1, further comprising a dielectric layer formed over the substrate, and wherein the control gate and floating gate are formed on the dielectric layer.

5. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for programming the single poly memory device, comprising:
applying a positive programming voltage to the control gate;
applying a positive programming voltage to the second bit line; and
applying 0 volts to the first bit line.

6. The method of claim 5, wherein the programming voltage applied to the control gate is approximately 3 volts.

7. The method of claim 5, wherein the programming voltage applied to the second bit line is approximately 6 volts.

8. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for programming the single poly memory device, comprising:
applying a positive programming voltage to the control gate;
applying a negative programming voltage to the first bit line; and
applying 0 volts to the second bit line.

9. The method of claim 8, wherein the programming voltage applied to the control gate is approximately 3 volts.

10. The method of claim 8, wherein the programming voltage applied to the first bit line is approximately −5 volts.

11. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for programming the single poly memory device, comprising:
applying a positive programming voltage to the control gate;
applying a positive programming voltage to the select input;
applying a negative programming voltage to the first bit line; and
applying 0 volts to the second bit line.

12. The method of claim 11, wherein the programming voltage applied to the control gate is approximately 5 volts.

13. The method of claim 11, wherein the programming voltage applied to the first bit line is approximately −3 volts.

14. The method of claim 11, wherein the programming voltage applied to the select input is approximately 2 volts.

15. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for erasing the single poly memory device, comprising:
applying a positive erase voltage to the control gate;
applying a positive erase voltage to the second bit line; and
applying 0 volts to the first bit line.

16. The method of claim 15, wherein the erase voltage applied to the control gate is approximately 7 volts.

17. The method of claim 15, wherein the programming voltage applied to the second bit line is approximately 5 volts.

18. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for erasing the single poly memory device, comprising:
applying a positive erase voltage to the control gate;
applying a negative erase voltage to the first bit line;
applying a positive erase voltage to the select line; and
applying 0 volts to the second bit line.

19. The method of claim 18, wherein the erase voltage applied to the control gate is approximately 7 volts.

20. The method of claim 18, wherein the programming voltage applied to the second bit line is approximately −2 volts.

21. The method of claim 18, wherein the programming voltage applied to the select lien is approximately 8 volts.

22. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for erasing the single poly memory device comprising exposing the floating gate to UV radiation.

23. In a single poly memory device comprising an access device including a control gate connected with the control gate input, a shared diffusion region, and a source diffusion region connected with a select input, and a storage device comprising a floating gate, the shared diffusion region, and a double diffusion structure, the double diffusion structure including a first diffusion region connected with a first bit line and a second diffusion region connected with a second bit line, a method for reading the single poly memory device comprising:
applying a positive read voltage to the control gate;
applying a positive read voltage to the second bit line;
applying a low voltage to the first bit line; and
applying a low voltage to the select input.

24. The method of claim 23, wherein the positive read voltage applied to the control gate is approximately 3 volts.

25. The method of claim 23 wherein the positive read voltage applied to the second bit line is approximately 1 volt.

26. The method of claim 23, wherein the low voltage applied to the first bit line is approximately 0 volts.

27. The method of claim 23, wherein the low voltage applied to the select line is approximately 0 volts.

28. The method of claim 23, wherein the voltages applied to the control gate, first bit line, second bit line, and the select input result in a high current through the single poly memory device when no charge or a positive charge is stored on the floating gate.

29. The method of claim 23, wherein the voltages applied to the control gate, first bit line, second bit line, and the select input result in a low current through the single poly memory device when a negative charge is stored on the floating gate.
